(19) United States
(12) Patent Application Publication
(10) Pub. No.: US 2026/0059873 A1
(43) Pub. Date: Feb. 26, 2026

(54) VERTICAL TRANSFER GATE STRUCTURES AND METHODS

(71) Applicant: Taiwan Semiconductor Manufacturing Company, Ltd., Hsinchu (TW)

(72) Inventors: Feng-Chien Hsieh, Pingtung City (TW); Wei-Li Hu, Tainan City (TW); Chien Nan Tu, Kaohsiung City (TW)

(73) Assignee: Taiwan Semiconductor Manufacturing Company, Ltd., Hsinchu (TW)

(21) Appl. No.: 18/813,528

(22) Filed: Aug. 23, 2024

(51) Int. Cl. H01L 27/146; H01L 29/66; H01L 29/762

(52) U.S. Cl. CPC H10F 39/182; H10D 44/00; H10D 44/01; H10F 39/014; H10F 39/807

(57) ABSTRACT

A semiconductor structure is provided that includes: a plurality of pixel sections arranged in a substrate, each pixel section having a plurality of sides; and first pixel section of the plurality of pixel sections including: a photo detector; and a vertical transfer gate (VTG) structure disposed above the photo detector, the VTG structure having a laterally extending body portion and a plurality of wall sections connected to end regions of the body portion that vertically extend into the substrate and laterally extend adjacent to a side of the pixel section.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum feature sizes are reduced, additional problems arise that should be addressed.

### BRIEF DESCRIPTION OF DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a plan or layout view illustrating a CMOS image sensor (CIS), according to some embodiments.

FIG. 1B is a schematic cross sectional view of the pixel area of the CMOS image sensor, according to some embodiments.

FIG. 2A is a schematic top view of a portion of a pixel structure of an image sensor that includes a plurality of sub-pixel regions, according to some embodiments.

FIG. 2B is a schematic cross sectional diagram depicting an example sub-pixel region along cut line A-A′ of FIG. 1A, according to some embodiments.

FIG. 3A is a schematic top view of a portion of a pixel structure that includes a plurality of pixel sections arranged in a substrate, according to some embodiments.

FIG. 3B is a schematic cross sectional diagram depicting an example sub-pixel region along cut line B-B′ of FIG. 3A, according to some embodiments.

FIG. 3C is a schematic cross sectional diagram depicting another example sub-pixel region along cut line B-B′ of FIG. 3A, according to some embodiments.

FIG. 3D is a schematic cross sectional diagram depicting another example sub-pixel region along cut line B-B′ of FIG. 3A, according to some embodiments.

FIG. 4A is a schematic top view of a portion of a pixel structure that includes a plurality of pixel sections arranged in a substrate, according to some embodiments.

FIG. 4B is a schematic cross sectional diagram depicting an example sub-pixel region along cut line C-C′ of FIG. 4A, according to some embodiments.

FIG. 4C is a schematic cross sectional diagram depicting another example sub-pixel region along cut line C-C′ of FIG. 4A, according to some embodiments.

FIG. 5A is a schematic top view of a portion of a pixel structure that includes a plurality of pixel sections arranged in a substrate, according to some embodiments.

FIG. 5B is a schematic cross sectional diagram depicting an example sub-pixel region along cutline D-D′ of FIG. 5A, according to some embodiments.

FIG. 5C is a schematic cross sectional diagram depicting another example sub-pixel region along cutline D-D′ of FIG. 5A, according to some embodiments.

FIG. 5D is a schematic cross sectional diagram depicting another example sub-pixel region along cutline D-D′ of FIG. 5A, according to some embodiments.

FIGS. 6A-6I are schematic top views of a portion of a pixel structure that includes a plurality of pixel sections arranged in a substrate, according to some embodiments.

FIG. 7A is a plot of quantum efficiency of an imaging device to convert incident photons from light into electrons versus wavelength of the light in nanometers, according to some embodiments.

FIGS. 7B-7F are schematic cross sectional diagrams depicting example pixel regions, according to some embodiments.

FIG. 8A is a schematic diagram illustrating an example layout for a plurality of pixel regions in a semiconductor imaging device, according to some embodiments.

FIG. 8B is a schematic cross sectional diagram depicting example pixel regions, according to some embodiments.

FIG. 8C is a schematic cross sectional diagram depicting example pixel regions, according to some embodiments.

FIG. 9 is a flow diagram of an example method for fabricating a semiconductor device having a vertical transfer gate, according to some embodiments.

FIGS. 10A-10H, are schematic cross-sectional diagrams of a semiconductor device at various stages of its fabrication process, according to some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting.

For the sake of brevity, techniques related to semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many conventional processes will only be mentioned briefly herein or will be omitted entirely without providing the well-known process details. As will be readily apparent to those skilled in the art upon a complete reading of the disclosure, the structures disclosed herein may be employed with a variety of technologies, and may be incorporated into a variety of semiconductor devices and products. Further, it is noted that semiconductor device structures include a varying number of components and that single components shown in the illustrations may be representative of multiple components.

Furthermore, spatially relative terms, such as “over”, “overlying”, “above”, “upper”, “top”, “under”, “underlying”, “below”, “lower”, “bottom”, and the like, may be used herein for ease of description to describe one element's or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. When a spatially relative term, such as those listed above, is used to describe a first element with respect to a second element, the first element may be directly on the other element, or intervening elements or layers may be present.

In addition, the present disclosure may repeat reference numerals and/or letters in the various examples. This repetition is for the purpose of simplicity and clarity and does not in itself dictate a relationship between the various embodiments and/or configurations discussed.

It is noted that references in the specification to “one embodiment,” “an embodiment,” “an example embodiment,” “exemplary,” “example,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to affect such feature, structure, or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

The following disclosure provides many different embodiments, or examples, for implementing different features of the disclosed subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. Throughout the description herein, unless otherwise specified, the same reference numeral in different figures refers to the same or similar component formed by a same or similar method using a same or similar material(s).

As used herein, the terms such as “first,” “second” and “third” describe various elements, components, regions, layers and/or sections, these elements, components, regions, layers, and/or sections should not be limited by these terms. These terms may be only used to distinguish one element, component, region, layer, or section from another. The terms such as “first,” “second” and “third” when used herein do not imply a sequence or order unless clearly indicated by the context.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same or equal if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” parallel can refer to a range of angular variation relative to 0° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°. For example, “substantially” perpendicular can refer to a range of angular variation relative to 90° that is less than or equal to ±10°, such as less than or equal to ±5° less than or equal to ±4°, less than or equal to ±3°, less than or equal to ±2°, less than or equal to ±1°, less than or equal to ±0.5°, less than or equal to ±0.1°, or less than or equal to ±0.05°.

Semiconductor image sensors are used to sense incoming visible or non-visible radiation, such as visible light, infrared light, etc. Complementary metal-oxide-semiconductor (CMOS) image sensors (CIS) are used in various applications, such as digital still cameras, mobile phones, tablets, goggles, etc. These image sensors utilize an array of pixels that absorb (e.g., sense) the incoming radiation and convert it into electrical signals.

A backside illumination (BSI) image sensor is a type of CIS device. A BSI image sensor includes a pixel region with an array of pixels or radiation-sensing regions formed on a substrate (e.g., a semiconductor substrate). The terms “radiation-sensing regions” and “pixels” may be used interchangeably throughout this disclosure. The pixels are configured to convert photons from the incident radiation to an electrical signal. The electrical signal is subsequently distributed to processing components attached to the BSI image sensor. The pixel region includes a pixel section structure that provide optical isolation between adjacent pixels. Further, the pixel region may include color filtering layers. The material of color filtering layers can be selected such that light with a desired wavelength passes through the color filtering layers, while light with other wavelengths is absorbed by the color filtering layers.

Improvements to CIS devices are desired. In accordance with some embodiments of the present disclosure, a vertical transfer gate (VTG) all around design structure is proposed that has a plurality of transfer gate walls to capture more electrons in the radiation sensing regions to reduce CIS lag. In accordance with some embodiments of the present disclosure, a VTG all around design structure is proposed that has a plurality of transfer gate walls that are disposed deeper in the radiation sensing regions to capture more electrons in the radiation sensing regions to reduce CIS lag.

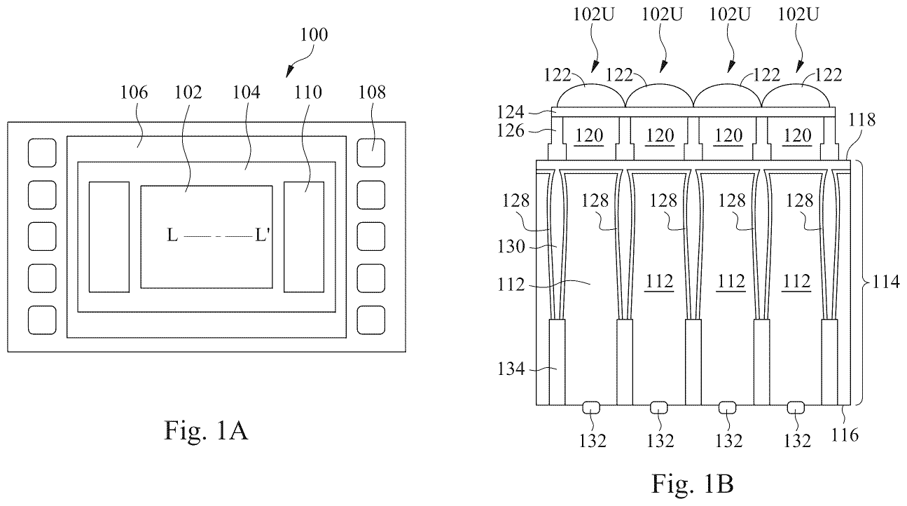

FIG. 1A is a plan or layout view illustrating an example CMOS image sensor (CIS) 100 according to some embodiments. The example CMOS image sensor 100 include a pixel area 102 in which a plurality of unit pixels are arranged in a matrix, and an optical isolation region 104 surrounding the pixel area 102. Further, the optical isolation region 104 is surrounded by a physical isolation area 106. In some embodiments, the CMOS image sensor 100 includes a plurality of pad electrodes 108 for wiring to outside circuitry. The example CMOS image sensor 100 further includes one or more black level calibration (BLC) area 110 which blocks incident light and provide a reference dark voltage current.

FIG. 1B illustrates a cross sectional view of the pixel area 102 of the CMOS image sensor 100 along cutline L-L′ of FIG. 1A in the pixel area 102, in accordance with some embodiments. The pixel area 102 includes a plurality of unit pixels 102U, each of which includes a photodiode layer 112 formed in a semiconductor substrate 114 (e.g., Si substrate) having a first surface 116 and an opposing second surface 118, a color filter 120 disposed over the second surface 118 and substantially aligning with the photodiode layer 112, and a micro-lens 122 disposed over and aligning with the color filter 120. In some embodiments, a liner dielectric layer 124 is disposed between the color filter 120 and the micro-lens 122. The CMOS image sensor 100 also includes a first isolation structure 126 to laterally separate adjacent color filters 120. The example CMOS image sensor 100 includes a second isolation structure 128, which is a deep trench isolation structure filled with one or more dielectric materials 130, disposed in the semiconductor substrate 114 to laterally separate adjacent photodiode layers 112. In addition, the CMOS image sensor 100 includes a transfer gate 132 coupled to the photodiode layer 112 disposed on the first surface 116 of the substrate 114. In some embodiments, a third isolation structure 134, which is a doped region implanted with, for example, boron, is disposed between and aligning with the second isolation structure 128 and the first surface 116, and functions as an electrical isolation structure. In some embodiments, each unit pixel 102U has a square or a rectangular shape in plan view and is surrounded by the first isolation structure 126, second isolation structure 128, and third isolation structure 134.

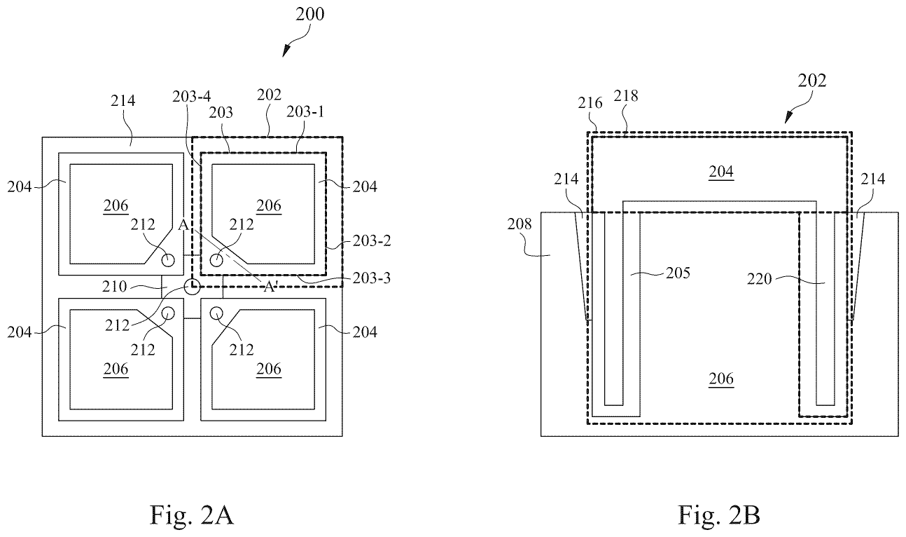

FIG. 2A is a schematic top view of a portion of a pixel structure 200 (e.g., unit pixel 102U) of an image sensor that includes a plurality of sub-pixel regions 202, according to some embodiments of the present disclosure. The pixel structure 200 includes a plurality of pixel sections 203 arranged in a substrate. Each pixel section 203 has a plurality of sides as viewed from a top view. In this example, each pixel section 203 has four sides (side 203-1, side 203-2, side 203-3, and side 203-4). The example sub-pixel region 202 and pixel section 203 include a gate poly region 204 for a vertical transfer gate (VTG) disposed above and around a photo detector 206 in the substrate. The sub-pixel region 202 also includes a floating diffusion (FD) region 210 and contacts 212, and may include shallow trench isolation features 214.

FIG. 2B is a schematic cross sectional diagram depicting an example sub-pixel region 202 along cut line A-A′ of FIG. 2A. In this example, the sub-pixel region 202 includes a gate poly region 204 and gate oxide 205 for a vertical transfer gate VTG disposed above and around a photo detector 206 in a substrate 208. The sub-pixel region 202 also includes shallow trench isolation features 214.

A VTG structure 216 comprising the gate poly region 204 and gate oxide 205 is disposed above the photo detector 206 in a pixel section 203. The VTG structure 216 has a laterally extending body portion 218 and a plurality of wall sections 220 connected to end regions of the body portion 218 that vertically extend into the substrate 208 and laterally extend adjacent to a side of the pixel section 203.

The substrate 208 may be a semiconductor substrate, such as a bulk semiconductor, a semiconductor-on-insulator (SOI) substrate, a semiconductor wafer, or the like, which may be doped (e.g., with a p-type or an n-type dopant) or undoped. Other substrates, such as a multi-layered or gradient substrate may also be used. In some embodiments, the semiconductor material of the substrate may include silicon.

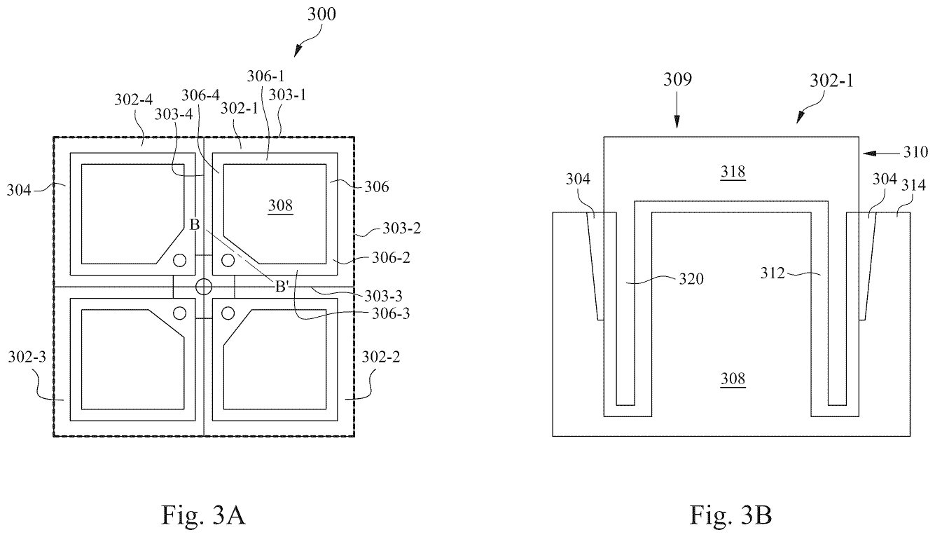

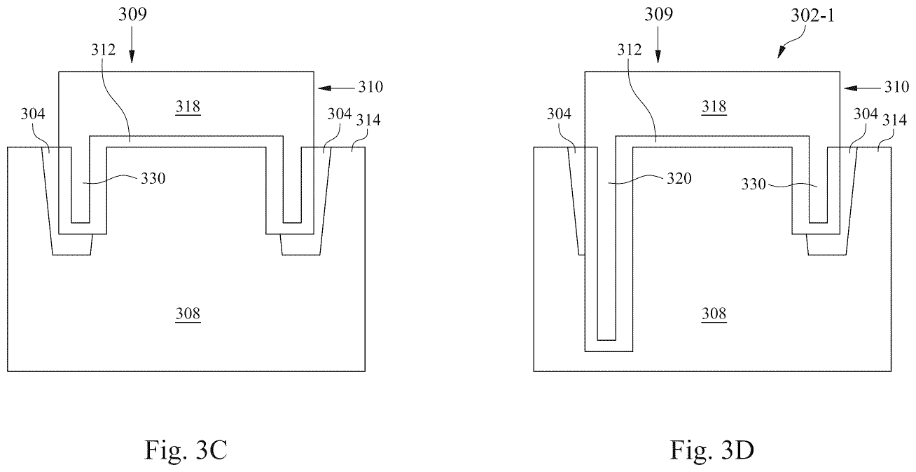

FIG. 3A is a schematic top view of a portion of a pixel structure 300 that includes a plurality of pixel sections (e.g., pixel section 302-1, pixel section 302-2, pixel section 302-3, pixel section 302-4) arranged in a substrate, according to some embodiments of the present disclosure. Each pixel section has a plurality of sides (side 303-1, side 303-2, side 303-3, side 303-4), four in this example. In this example, each pixel section is separated from neighboring pixel sections of the plurality of pixel sections by an isolation layer (e.g., shallow trench isolation features 304) at borders between the pixel section and neighboring pixel sections.

A VTG structure 306 comprising a gate poly region (shown) and gate oxide (not shown) is disposed above and around a photo detector 308 in a pixel section (e.g., pixel section 302-1). The VTG structure 306 has a plurality of wall sections (wall section 306-1, wall section 306-2, wall section 306-3, wall section 306-4) that vertically extend into the substrate and laterally extend adjacent to a side (side 303-1, side 303-2, side 303-3, side 303-4) of the pixel section (e.g., pixel section 302-1). In this example, each wall section extends a distance that is greater than half the length of the corresponding side to which the wall section is adjacent. For example, wall section 306-1 extends a distance greater than half the length of the side 303-1.

FIG. 3B is a schematic cross sectional diagram depicting an example sub-pixel region in pixel section 302-1 along cut line B-B′ of FIG. 3A. In this example, the sub-pixel region includes a VTG structure 309 comprising a gate poly region 310 and gate oxide 312 for a VTG disposed above and around a photo detector 308 in a pixel section (e.g., pixel section 302-1, pixel section 302-2, pixel section 302-3, or pixel section 302-4) in a substrate 314. The sub-pixel region also includes shallow trench Isolation features 304.

The VTG structure 309 has a laterally extending body portion 318 and a plurality of wall sections 320 connected at end regions of the body portion 318 that vertically extend into the substrate 314 and laterally extend adjacent to a side (e.g., side 303-1, side 303-2, side 303-3, or side 303-4) of the pixel section (e.g., pixel section 302-1, pixel section 302-2, pixel section 302-3, or pixel section 302-4). The plurality of wall sections 320 are disposed in a portion of the pixel section that is isolated by an isolation layer (e.g., shallow trench isolation features 304) from neighboring pixel sections.

FIG. 3C is a schematic cross sectional diagram depicting another example sub-pixel region in pixel section 302-1 along cut line B-B′ of FIG. 3A. In this example, the sub-pixel region includes a VTG structure 309 comprising a gate poly region 310 and gate oxide 312 for a VTG disposed above and around a photo detector 308 in a pixel section (e.g., pixel section 302-1, pixel section 302-2, pixel section 302-3, or pixel section 302-4) in a substrate 314. The sub-pixel region also includes shallow trench Isolation features 304.

The VTG structure 309 has a laterally extending body portion 318 and a plurality of wall sections 330 connected at end regions of the body portion 318 that vertically extend into the substrate 314 and laterally extend adjacent to a side (e.g., side 303-1, side 303-2, side 303-3, or side 303-4) of the pixel section (e.g., pixel section 302-1, pixel section 302-2, pixel section 302-3, or pixel section 302-4). The plurality of wall sections 330 are disposed in a portion of the pixel section that is isolated by an isolation layer (e.g., shallow trench isolation features 304) from neighboring pixel sections.

The example sub-pixel region of FIG. 3C is similar to the example sub-pixel region of FIG. 3B, but differs in the length of wall sections. In the example of FIG. 3B, the wall sections 320 have a length that is longer than the length of the wall sections 330 in the example of FIG. 3C. The length of the wall sections can be tuned for light in a specific wavelength band that the sub-pixel area is configured to detect. For example, if the sub-pixel area is configured for detecting red light the length of the wall sections may be in a first predetermined length range, if the sub-pixel area is configured for detecting green light the length of the wall sections may be in a second predetermined length range, if the sub-pixel area is configured for detecting blue light the length of the wall sections may be in a third predetermined length range, if the sub-pixel area is configured for detecting clear light (e.g., white light) the length of the wall sections may be in a fourth predetermined length range, if the sub-pixel area is configured for detecting infrared light the length of the wall sections may be in a fifth predetermined length range, etc.

FIG. 3D is a schematic cross sectional diagram depicting another example sub-pixel region in pixel section 302-1 along cut line B-B′ of FIG. 3A. In this example, the sub-pixel region includes a VTG structure 309 comprising a gate poly region 310 and gate oxide 312 for a VTG disposed above and around a photo detector 308 in a pixel section (e.g., pixel section 302-1, pixel section 302-2, pixel section 302-3, or pixel section 302-4) in a substrate 314. The sub-pixel region also includes shallow trench Isolation features 304.

The VTG structure 309 has a laterally extending body portion 318 and a plurality of wall sections 320, 330 connected at end regions of the body portion 318 that vertically extend into the substrate 314 and laterally extend adjacent to a side (e.g., side 303-1, side 303-2, side 303-3, or side 303-4) of the pixel section (e.g., pixel section 302-1, pixel section 302-2, pixel section 302-3, or pixel section 302-4). The plurality of wall sections 320, 330 are disposed in a portion of the pixel section that is isolated by an isolation layer (e.g., shallow trench isolation features 304) from neighboring pixel sections.

The example sub-pixel region of FIG. 3D is similar to the example sub-pixel region of FIGS. 3B and 3C but differs in the length of wall sections. In the example of FIG. 3D, the wall sections 320 have a length that is longer than the length of the wall sections 330. The length of the wall sections can be tuned for light in a specific wavelength band that the sub-pixel area is configured to detect. For example, if the sub-pixel area is configured for detecting red light the length of the wall sections may be in a first predetermined length range, if the sub-pixel area is configured for detecting green light the length of the wall sections may be in a second predetermined length range, if the sub-pixel area is configured for detecting blue light the length of the wall sections may be in a third predetermined length range, if the sub-pixel area is configured for detecting clear light the length of the wall sections may be in a fourth predetermined length range, if the sub-pixel area is configured for detecting infrared light the length of the wall sections may be in a fifth predetermined length range, etc.

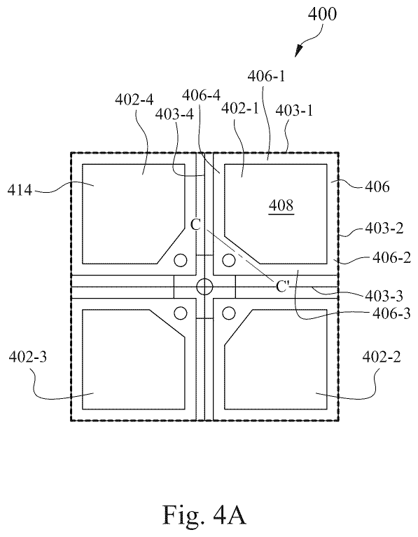

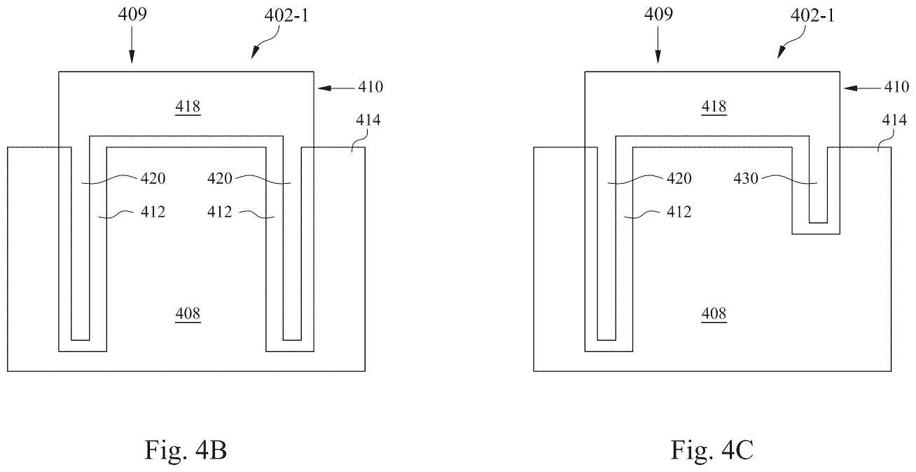

FIG. 4A is a schematic top view of a portion of a pixel structure 400 that includes a plurality of pixel sections (e.g., pixel section 402-1, pixel section 402-2, pixel section 402-3, pixel section 402-4) arranged in a substrate 414, according to some embodiments of the present disclosure. Each pixel section has a plurality of sides (side 403-1, side 403-2, side 403-3, side 403-4), four in this example. In this example, each pixel section is separated from neighboring pixel sections of the plurality of pixel sections, but are not isolated from neighboring pixel sections by an isolation layer at borders between the pixel section and neighboring pixel sections.

A VTG structure 406 comprising a gate poly region (shown) and gate oxide (not shown) is disposed above and around a photo detector 408 in a pixel section (e.g., pixel section 402-1). The VTG structure 406 has a plurality of wall sections (wall section 406-1, wall section 406-2, wall section 406-3, wall section 406-4) that vertically extend into the substrate 414 and laterally extend adjacent to a side (e.g., side 403-1, side 403-2, side 403-3, side 403-4) of the pixel section (e.g., pixel section 402-1). In this example, each wall section extends a distance that is greater than half the length of the corresponding side to which the wall section is adjacent. For example, wall section 406-1 extends a distance greater than half the length of the side 403-1.

FIG. 4B is a schematic cross sectional diagram depicting an example sub-pixel region in pixel section 402-1 along cut line C-C′ of FIG. 4A. In this example, the sub-pixel region includes a VTG structure 409 comprising a gate poly region 410 and gate oxide 412 for a VTG disposed above and around a photo detector 408 in a pixel section (e.g., pixel section 402-1, 402-2, 402-3, or 402-4) in a substrate 414.

The VTG structure 409 has a laterally extending body portion 418 and a plurality of wall sections 420 connected at end regions of the body portion 418 that vertically extend into the substrate 414 and laterally extend adjacent to a side (e.g., side 403-1, side 403-2, side 403-3, or side 403-4) of the pixel section (e.g., pixel section 402-1, pixel section 402-2, pixel section 402-3, or pixel section 402-4). The plurality of wall sections 420 are disposed in a portion of the pixel section and are not isolated from neighboring pixel sections by an isolation layer at borders between the pixel section and neighboring pixel sections.

FIG. 4C is a schematic cross sectional diagram depicting another example sub-pixel region in pixel section 402-1 along cut line C-C′ of FIG. 4A. In this example, the sub-pixel region includes a VTG structure 409 comprising a gate poly region 410 and gate oxide 412 for a VTG disposed above and around a photo detector 408 in a pixel section (e.g., pixel section 402-1, pixel section 402-2, pixel section 402-3, or pixel section 402-4) in a substrate 414.

The VTG structure 409 has a laterally extending body portion 418 and a plurality of wall sections 420, 430 connected at end regions of the body portion 418 that vertically extend into the substrate 414 and laterally extend adjacent to a side (e.g., side 403-1, side 403-2, side 403-3, or side 403-4) of the pixel section (e.g., pixel section 402-1, pixel section 402-2, pixel section 402-3, or pixel section 402-4). The plurality of wall sections 420, 430 are disposed in a portion of the pixel section and are not isolated from neighboring pixel sections by an isolation layer at borders between the pixel section and neighboring pixel sections.

The example sub-pixel region of FIG. 4C is similar to the example sub-pixel region of FIG. 4B, but differs in the length of wall sections. In the example of FIG. 4B, the wall sections 420 have a length that is longer than the length of the wall sections 430. The length of the wall sections can be tuned for light in a specific wavelength band that the sub-pixel area is configured to detect. For example, if the sub-pixel area is configured for detecting red light the length of the wall sections may be in a first predetermined length range, if the sub-pixel area is configured for detecting green light the length of the wall sections may be in a second predetermined length range, if the sub-pixel area is configured for detecting blue light the length of the wall sections may be in a third predetermined length range, if the sub-pixel area is configured for detecting clear light the length of the wall sections may be in a fourth predetermined length range, if the sub-pixel area is configured for detecting infrared light the length of the wall sections may be in a fifth predetermined length range, etc.

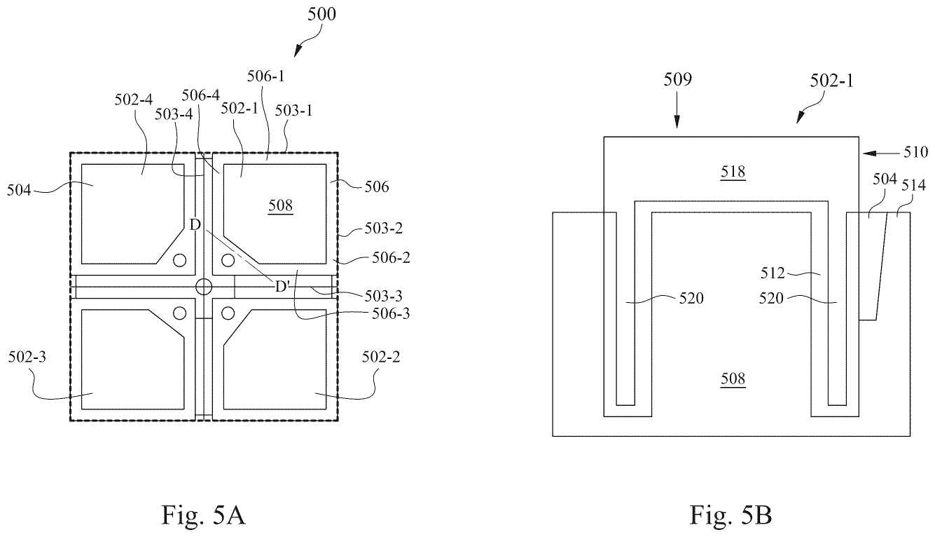

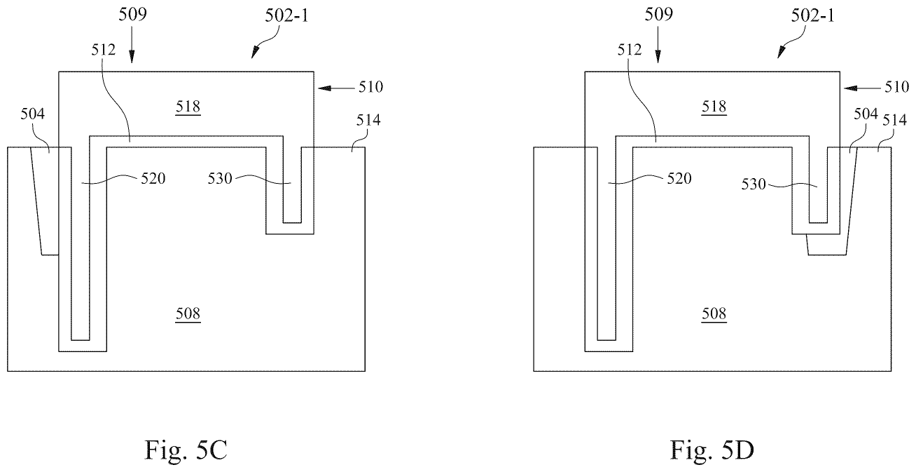

FIG. 5A is a schematic top view of a portion of a pixel structure 500 that includes a plurality of pixel sections (e.g., pixel section 502-1, pixel section 502-2, pixel section 502-3, pixel section 502-4) arranged in a substrate, according to some embodiments of the present disclosure. Each pixel section has a plurality of sides (side 503-1, side 503-2, side 503-3, side 503-4), four in this example. In this example, each pixel section is separated from neighboring pixel sections of the plurality of pixel sections, wherein some pixel sections are isolated from a first neighboring pixel section by an isolation layer at a border between the pixel section and the first neighboring pixel section and are not isolated from a second neighboring pixel section by an isolation layer at a border between the pixel section and second neighboring pixel section.

A VTG structure 506 comprising a gate poly region (shown) and gate oxide (not shown) is disposed above and around a photo detector 508 in a pixel section (e.g., pixel section 502-1). The VTG structure 506 has a plurality of wall sections (wall section 506-1, wall section 506-2, wall section 506-3, wall section 506-4) that vertically extend into the substrate and laterally extend adjacent to a side (side 503-1, side 503-2, side 503-3, side 503-4) of the pixel section (e.g., pixel section 502-1). In this example, each wall section extends a distance that is greater than half the length of the corresponding side to which the wall section is adjacent. For example, wall section 506-1 extends a distance greater than half the length of the side 503-1.

FIG. 5B is a schematic cross sectional diagram depicting an example sub-pixel region in pixel section 502-1 along cutline D-D′ of FIG. 5A. In this example, the sub-pixel region includes a VTG structure 509 comprising a gate poly region 510 and gate oxide 512 for a VTG disposed above and around a photo detector 508 in a pixel section (e.g., pixel section 502-1, pixel section 502-2, pixel section 502-3, or pixel section 502-4) in a substrate 514.

The VTG structure 509 has a laterally extending body portion 518 and a plurality of wall sections 520 connected at end regions of the body portion 518 that vertically extend into the substrate 514 and laterally extend adjacent to a side (e.g., side 503-1, side 503-2, side 503-3, or side 503-4) of the pixel section (e.g., pixel section 502-1, pixel section 502-2, pixel section 502-3, or pixel section 502-4). The plurality of wall sections 520 are disposed in a portion of the pixel section, wherein a first wall section of the plurality of wall sections 520 is isolated from a first neighboring pixel section by an isolation layer (e.g., STI features 504) at a border between the pixel section and the first neighboring pixel section, and a second wall section of the plurality of wall sections 520 is not isolated from a second neighboring pixel section by an isolation layer at a border between the pixel section and the second neighboring pixel section.

FIG. 5C is a schematic cross sectional diagram depicting another example sub-pixel region in pixel section 502-1 along cutline D-D′ of FIG. 5A. In this example, the sub-pixel region includes a VTG structure 509 comprising a gate poly region 510 and gate oxide 512 for a VTG disposed above and around a photo detector 508 in a pixel section (e.g., pixel section 502-1, pixel section 502-2, pixel section 502-3, or pixel section 502-4) in a substrate 514.

The VTG structure 509 has a laterally extending body portion 518 and a plurality of wall sections 520, 530 connected at end regions of the body portion 518 that vertically extend into the substrate 514 and laterally extend adjacent to a side (e.g., side 503-1, side 503-2, side 503-3, or side 503-4) of the pixel section (e.g., pixel section 502-1, pixel section 502-2, pixel section 502-3, or pixel section 502-4). The plurality of wall sections 520, 530 are disposed in a portion of the pixel section, wherein a first wall section 520 is isolated from a first neighboring pixel section by an isolation layer (e.g., STI features 504) at a border between the pixel section and the first neighboring pixel section, and a second wall section 530 is not isolated from a second neighboring pixel section by an isolation layer at a border between the pixel section and the second neighboring pixel section.

The example sub-pixel region of FIG. 5C is similar to the example sub-pixel region of FIG. 5B, but differs in the length of wall sections. In the example of FIG. 5B, the wall section 420 has a length that is longer than the length of the wall section 430. The length of the wall sections can be tuned for light in a specific wavelength band that the sub-pixel area is configured to detect. For example, if the sub-pixel area is configured for detecting red light the length of the wall sections may be in a first predetermined length range, if the sub-pixel area is configured for detecting green light the length of the wall sections may be in a second predetermined length range, if the sub-pixel area is configured for detecting blue light the length of the wall sections may be in a third predetermined length range, if the sub-pixel area is configured for detecting clear light the length of the wall sections may be in a fourth predetermined length range, if the sub-pixel area is configured for detecting infrared light the length of the wall sections may be in a fifth predetermined length range, etc.

FIG. 5D is a schematic cross sectional diagram depicting another example sub-pixel region in pixel section 502-1 along cutline D-D′ of FIG. 5A. In this example, the sub-pixel region includes a VTG structure 509 comprising a gate poly region 510 and gate oxide 512 for a VTG disposed above and around a photo detector 508 in a pixel section (e.g., pixel section 502-1, pixel section 502-2, pixel section 502-3, or pixel section 502-4) in a substrate 514.

The VTG structure 509 has a laterally extending body portion 518 and a plurality of wall sections 520, 530 connected at end regions of the body portion 518 that vertically extend into the substrate 514 and laterally extend adjacent to a side (e.g., side 503-1, side 503-2, side 503-3, or side 503-4) of the pixel section (e.g., pixel section 502-1, pixel section 502-2, pixel section 502-3, or pixel section 502-4). The plurality of wall sections 520, 530 are disposed in a portion of the pixel section, wherein a first wall section 520 is not isolated from a first neighboring pixel section by an isolation layer at a border between the pixel section and the first neighboring pixel section, and a second wall section 530 is isolated from a second neighboring pixel section by an isolation layer (e.g., STI features 504) at a border between the pixel section and the second neighboring pixel section.

The example sub-pixel region of FIG. 5D is similar to the example sub-pixel region of FIG. 5B, but differs in the length of wall sections. In the example of FIG. 5B, the wall section 420 has a length that is longer than the length of the wall section 430. The length of the wall sections can be tuned for light in a specific wavelength band that the sub-pixel area is configured to detect. For example, if the sub-pixel area is configured for detecting red light the length of the wall sections may be in a first predetermined length range, if the sub-pixel area is configured for detecting green light the length of the wall sections may be in a second predetermined length range, if the sub-pixel area is configured for detecting blue light the length of the wall sections may be in a third predetermined length range, if the sub-pixel area is configured for detecting clear light the length of the wall sections may be in a fourth predetermined length range, if the sub-pixel area is configured for detecting infrared light the length of the wall sections may be in a fifth predetermined length range, etc.

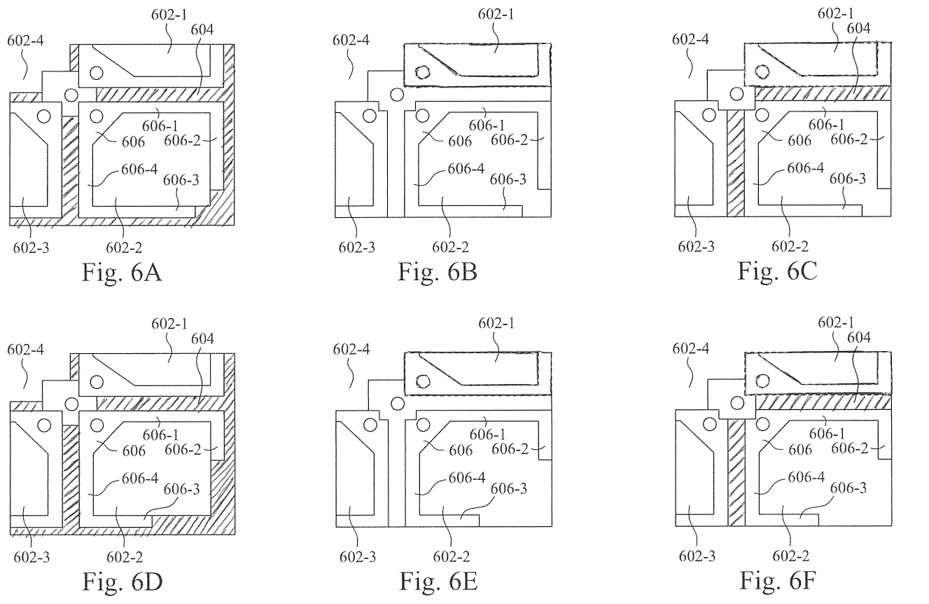

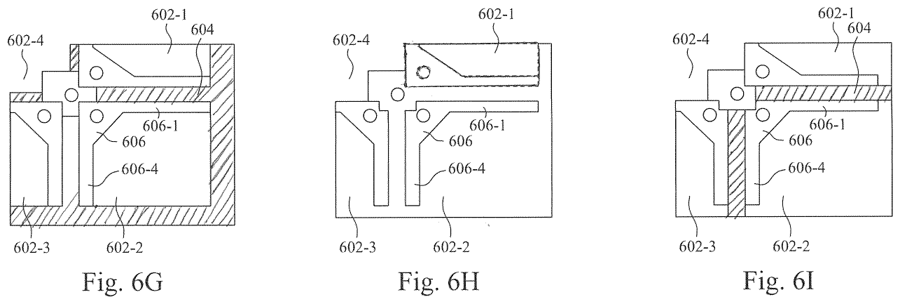

FIGS. 6A-6I are schematic top views of a portion of a pixel structure that includes a plurality of pixel sections (e.g., pixel section 602-1, pixel section 602-2, pixel section 602-3, pixel section 602-4) arranged in a substrate, according to some embodiments of the present disclosure. In the examples of FIGS. 6A, 6D, and 6G, each pixel section is separated from neighboring pixel sections of the plurality of pixel sections by an isolation layer (e.g., shallow trench isolation features 604) at borders between the pixel section and neighboring pixel sections. These pixel sections are fully isolated from neighboring pixel sections of the plurality of pixel sections by an isolation layer.

In the examples of FIGS. 6B, 6E, and 6H, the pixel sections are not isolated from neighboring pixel sections by an isolation layer at borders between the pixel section and neighboring pixel sections. These pixel sections are non-isolated from neighboring pixel sections.

In the examples of FIGS. 6C, 6F, and 6I, each pixel section is separated from neighboring pixel sections of the plurality of pixel sections, wherein some pixel sections are isolated from a first neighboring pixel section by an isolation layer at a border between the pixel section and the first neighboring pixel section and are not isolated from a second neighboring pixel section by an isolation layer (e.g., STI features 604) at a border between the pixel section and second neighboring pixel section. These pixel sections are partially isolated from neighboring pixel sections of the plurality of pixel sections by an isolation layer.

In the examples of FIGS. 2A-2B, 3A-3D, 4A-4C, and 5A-5D, the semiconductor structure included a plurality of pixel sections. In these examples, each pixel section included a VTG structure comprising a plurality of vertically extending wall sections, and each VTG structure formed a closed shape from a top view around its pixel section. In these examples, each pixel section included four sides and four corners, the VTG structure with its plurality of vertically extending wall sections included four wall sections that extend laterally along the four sides of the pixel section, each of the four wall sections substantially extended an entire length along a side of the pixel section, and adjacent to each of the four corners two of the four wall sections connected.

In the examples of FIGS. 6A, 6B, and 6C, the semiconductor structure includes a plurality of pixel sections. In these examples, each pixel section includes a VTG structure 606 comprising a plurality of vertically extending wall sections (e.g., wall section 606-1, wall section 606-2, wall section 606-3, wall section 606-4), and each VTG structure 606 forms an open shape from a top view around its pixel section wherein a corner in the pixel section is open and not enclosed by the VTG structure 606. The VTG structure 606 is open at one corner. In these examples, each pixel section includes four sides and four corners, the VTG structure 606 with its plurality of vertically extending wall sections includes four wall sections that extend laterally along the four sides of the pixel section, each of the four wall sections substantially extended an entire length along a side of the pixel section, and adjacent to three of the four corners two of the four wall sections connect. In this example, wall sections 606-1 and 606-2 connect at a first corner, wall sections 606-3 and 606-4 connect at a second corner, and wall sections 606-4 and 606-1 connect at a third corner. Adjacent to the fourth corner, wall sections 606-2 and 606-3 do not connect.

In the examples of FIGS. 6D, 6E, and 6F, the semiconductor structure includes a plurality of pixel sections. In these examples, each pixel section includes a VTG structure 606 comprising a plurality of vertically extending wall sections (e.g., wall section 606-1, wall section 606-2, wall section 606-3, wall section 606-4), and each VTG structure 606 forms an open shape from a top view around its pixel section wherein a corner and approximately half of a side in the pixel section is open and not enclosed by the VTG structure 606. The VTG structure 606 is open at one corner and approximately half of one side in the pixel section. In these examples, each pixel section includes four sides and four corners, the VTG structure 606 with its plurality of vertically extending wall sections includes four wall sections that extend laterally along the four sides of the pixel section, three of the four wall sections substantially extends an entire length along a side of the pixel section, one of the four wall sections substantially extends approximately half the length along one side of the pixel section and adjacent to three of the four corners two of the four wall sections connect. In this example, wall sections 606-1 and 606-4 substantially extend an entire length along a side of the pixel section and wall sections 606-2 and 606-3 substantially extend approximately half a length along a side of the pixel section. Wall section 606-1 and wall section 606-2 connect at a first corner, wall sections 606-3 and 606-4 connect at a second corner, and wall sections 606-4 and 606-1 connect at a third corner. Adjacent to the fourth corner, wall sections 606-2 and 606-3 do not connect.

In the examples of FIGS. 6G, 6H, and 6I, the semiconductor structure includes a plurality of pixel sections. In these examples, each pixel section includes a VTG structure 606 comprising a plurality of vertically extending wall sections (e.g., wall section 606-1, wall section 606-4), and each VTG structure 606 forms an open shape from a top view around its pixel section wherein two sides in the pixel section are enclosed by the VTG structure 606. The VTG structure 606 is open on two sides of the pixel section. In these examples, each pixel section includes four sides and four corners, the VTG structure 606 with its plurality of vertically extending wall sections includes two wall sections that extend laterally along two of the four sides of the pixel section, the two wall sections substantially extends an entire length along a side of the pixel section, and adjacent to one of the two corners connect. In this example, wall sections 606-1 and 606-4 substantially extend an entire length along a side of the pixel section and wall sections 606-1 and 606-4 connect at a corner. Adjacent to the other three corners, no wall sections connect.

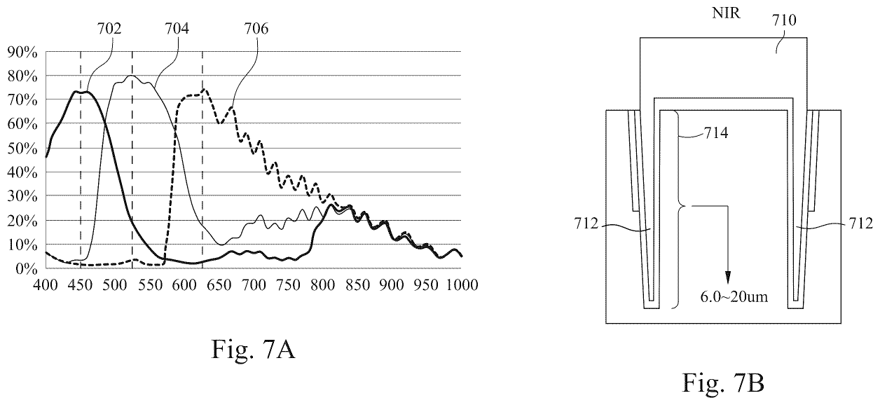

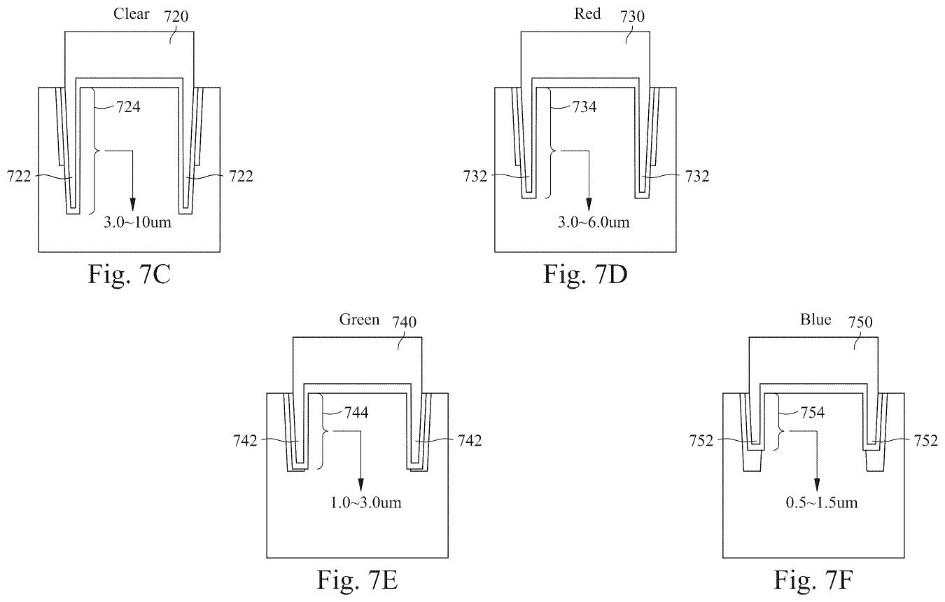

FIG. 7A is a plot of quantum efficiency of an imaging device to convert incident photons from light into electrons versus wavelength of the light in nanometers. This figure illustrates that a first plot 702 of the Quantum efficiency (QE) for blue light is at a peak at a first wavelength (e.g., approximately 450 nm), a second plot 704 of the QE for green light is at a peak at a second wavelength (e.g., approximately 625 nm), and a third plot 706 of the QE for red light is at a peak at a third wavelength (e.g., approximately 625 nm).

FIGS. 7B-7F are schematic cross sectional diagrams depicting example pixel regions. These examples provide example configurations of VTG wall depth in sub-pixel regions to maximize the capture of electrons for imaging devices configured to sense light in a specific light wavelength band.

In the example of FIG. 7B, the pixel region is configured for sensing light in the NIR band. The VTG structure 710 includes walls 712 with a wall depth 714 of approximately 6.0 μm (micrometers) to approximately 20 μm for optimizing the VTG structure to collect electrons from a photodetector configured to sense light in the NIR band.

In the example of FIG. 7C, the pixel region is configured for sensing light in the clear band. The VTG structure 720 includes walls 722 with a wall depth 724 of approximately 3.0 μm to approximately 10 μm for optimizing the VTG structure to collect electrons from a photodetector configured to sense light in the clear band.

In the example of FIG. 7D, the pixel region is configured for sensing light in the red band. The VTG structure 730 includes walls 732 with a wall depth 734 of approximately 3.0 μm to approximately 6.0 μm for optimizing the VTG structure to collect electrons from a photodetector configured to sense light in the red band.

In the example of FIG. 7E, the pixel region is configured for sensing light in the green band. The VTG structure 740 includes walls 742 with a wall depth 744 of approximately 1.0 μm to approximately 3.0 μm for optimizing the VTG structure to collect electrons from a photodetector configured to sense light in the green band.

In the example of FIG. 7F, the pixel region is configured for sensing light in the blue band. The VTG structure 750 includes walls 752 with a wall depth 754 of approximately 0.5 μm to approximately 1.5 μm for optimizing the VTG structure to collect electrons from a photodetector configured to sense light in the blue band.

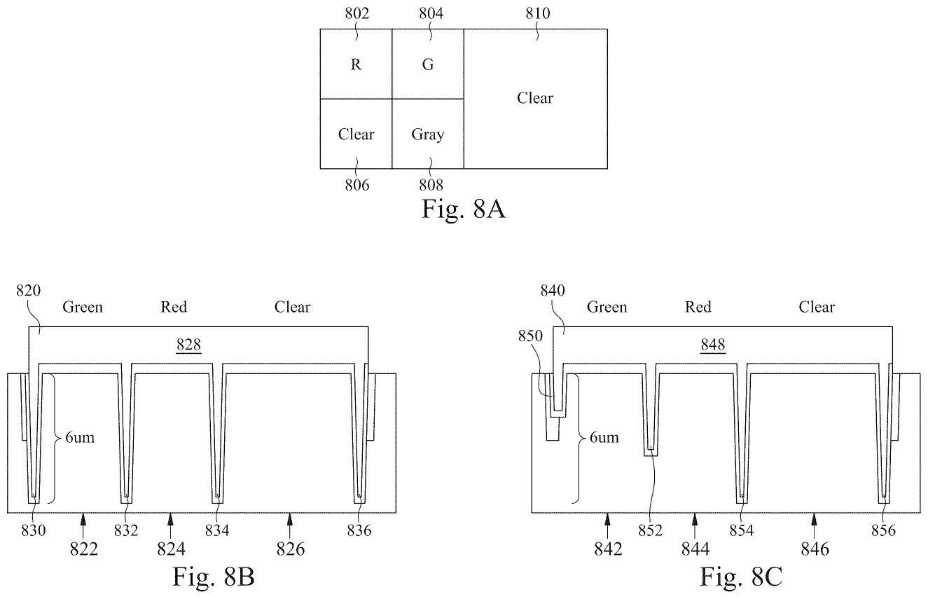

FIG. 8A is a schematic diagram illustrating an example layout for a plurality of pixel regions in a semiconductor imaging device. In this example, a first region 802 is configured to sense red light, a second region 804 is configured to sense green light, a third region 806 is configured to sense clear light, a fourth region 808 is configured to sense gray, and a fifth region 810 is configured to sense clear light.

FIG. 8B is a schematic cross sectional diagram depicting example pixel regions. In this example, a VTG structure 820 is provided that can collect electrons from a green pixel region 822, a red pixel region 824, and a clear pixel region 826. The VTG structure 820 includes a body portion 828 and a plurality of vertically extending wall sections (wall section 830, wall section 832, wall section 834, wall section 836). Wall sections 830 and 832 sense electrons in the green pixel region 822, wall sections 832 and 834 sense electrons in the red pixel region 824, and wall sections 834 and 836 sense electrons in the clear pixel region 826. In this example, all of the wall sections 830, 832, 834, 836 have a depth of 6 μm. Wall sections having this depth may be optimized for the red pixel region 824 and the clear pixel region 826, but not for the green pixel region 822.

FIG. 8C is a schematic cross sectional diagram depicting example pixel regions. In this example, a VTG structure 840 is provided that can collect electrons from a green pixel region 842, a red pixel region 844, and a clear pixel region 846. In this example, the VTG structure spans four pixels, one pixel each for the green pixel region 842, and the red pixel region 844, and two pixels for the clear pixel region 846. The VTG structure 840 includes a body portion 848 and a plurality of vertically extending wall sections (wall section 850, wall section 852, wall section 854, wall section 856). Wall sections 850 and 852 sense electrons in the green pixel region 842, wall sections 852 and 854 sense electrons in the red pixel region 844, and wall sections 854 and 856 sense electrons in the clear pixel region 846. In this example, all of the wall sections 850, 852, 854, 856 have different depths. In some embodiments, wall section 850 has a depth of approximately 1 μm, wall section 852 has a depth of approximately 3 μm, wall section 854 has a depth of approximately 6 μm, and wall section 856 has a depth of approximately 6 μm. Wall sections having these depths may be optimized for the green pixel region 842 (with approximately 1 to approximately 3 μm optimal depth), the red pixel region 844 (with approximately 3 to approximately 6 μm optimal depth), and the clear pixel region 846 (with approximately 3 to approximately 10 μm optimal depth).

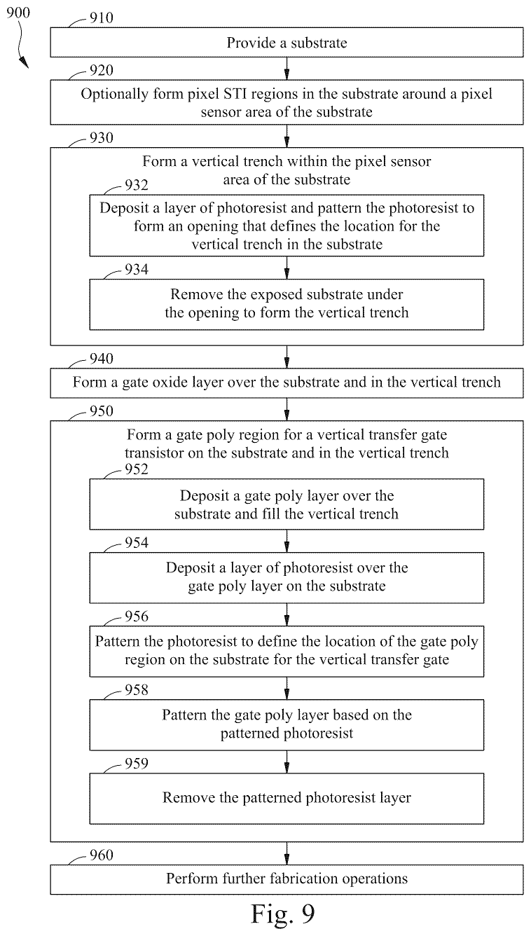

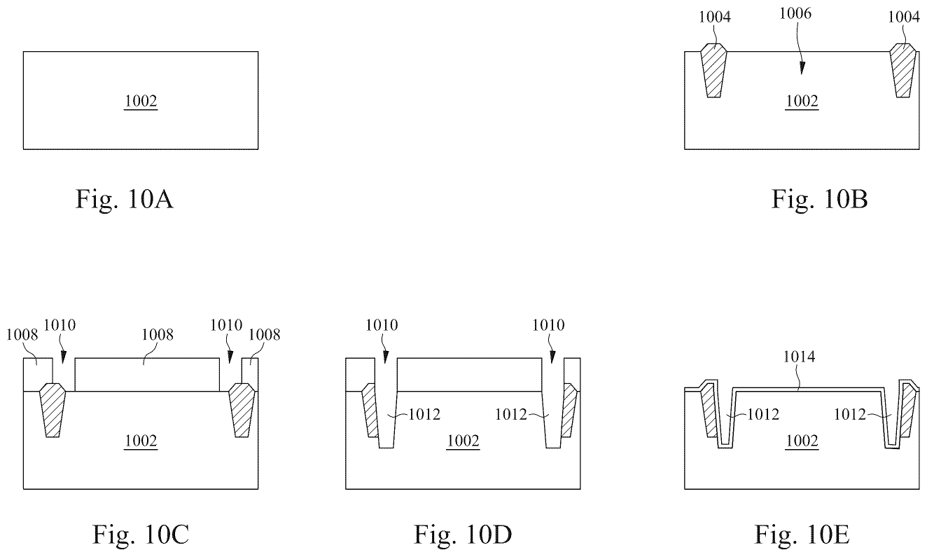

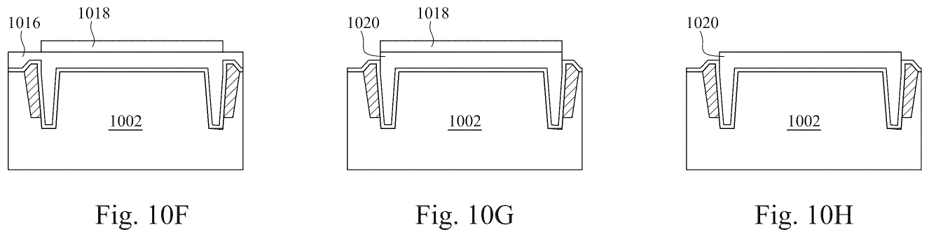

FIG. 9 is a flow diagram of an example method 900 for fabricating a semiconductor device having a vertical transfer gate, according to some embodiments. For illustrative purposes, the operations illustrated in FIG. 9 will be described with reference to FIGS. 10A-10H, which show cross-sectional views of a semiconductor device at various stages of its fabrication process, according to some embodiments. Operations can be performed in a different order or not performed depending on specific applications. It should be noted that method 900 may not produce a complete semiconductor device. Accordingly, it is understood that additional processes can be provided before, during, and after method, and that some other processes may only be briefly described herein. In some figures, some reference numbers of components or features illustrated therein may be omitted to avoid obscuring other components or features; this is for ease of depicting the figures.

The method 900 is merely an example, and is not intended to limit the present disclosure beyond what is explicitly recited in the claims. Additional steps may be provided before, during, and after example method 900, and some of the steps described can be moved, replaced, or eliminated for additional embodiments of example method 900. Additional features may be added in the semiconductor device depicted in the figures and some of the features described below can be replaced, modified, or eliminated in other embodiments of the semiconductor device.

It is understood that parts of the semiconductor device may be fabricated by typical semiconductor technology process flow, and thus some processes are only briefly described herein. Further, the exemplary semiconductor devices may include various other devices and features, such as other types of devices such as additional transistors, bipolar junction transistors, resistors, capacitors, inductors, diodes, fuses, and/or other logic devices, etc., but is simplified for a better understanding of concepts of the present disclosure. In some embodiments, the exemplary devices include a plurality of semiconductor devices (e.g., transistors), including PFETs, NFETs, etc., which may be interconnected. Moreover, it is noted that the operations of method 900, including any descriptions given with reference to the Figures are merely exemplary and are not intended to be limiting beyond what is specifically recited in the claims that follow.

At block 910, the method 900 includes providing a substrate. Referring to the example of FIG. 10A, in an embodiment of block 910, a substrate 1002 is provided. The substrate 1002 may be a semiconductor substrate, such as a bulk semiconductor, a semiconductor-on-insulator (SOI) substrate, a semiconductor wafer, or the like, which may be doped (e.g., with a p-type or an n-type dopant) or undoped. Other substrates, such as a multi-layered or gradient substrate may also be used. In some embodiments, the semiconductor material of the substrate 1002 may include silicon. In various embodiments, the substrate 1002 is planar with a uniform thickness.

At block 920, the method 900 includes optionally forming a pixel STI region in the substrate around a pixel sensor area of a pixel in the substrate. Referring to the example of FIG. 10B, in an embodiment of block 920, a pixel STI region 1004 is formed in the substrate 1002 around a pixel sensor area 1006 of the substrate 1002. The specific approach by which the pixel STI region 1004 is formed is beyond the scope of the present disclosure. However, it is to be understood that any approach can be employed. In some embodiments, the pixel STI region 1004 is formed as a dielectric region buried in the substrate 1002.

At block 930, the method 900 includes forming a vertical trench in the pixel sensor area of the substrate. The vertical trench is formed as part of forming a transfer transistor in the pixel sensor area. The transfer transistor is formed to connect a photodetector, such as a photodiode, to a charge storage node in the pixel. The vertical trench laterally extends along a plurality of sides of a pixel section in the substrate that bounds the pixel sensor area (e.g., side 203-1, side 203-2, side 203-3, and side 203-4 of pixel section 203; side 303-1, side 303-2, side 303-3, and side 303-4 of pixel section 302-1; side 403-1, side 403-2, side 403-3, and side 403-4 of pixel section 402-1; side 503-1, side 503-2, side 503-3, and side 503-4 of pixel section 502-1). In various embodiments, the vertical trench vertically extends a predetermined depth that is determined based on a light wavelength band to be sensed by a photodetector formed in the pixel sensing area (e.g., wall depth 714, wall depth 724, wall depth 734, wall depth 744, wall depth 754). In various embodiments, forming a vertical trench involves performing blocks 932 and block 934.

At block 932, the method 900 includes depositing a layer of photoresist on the substrate and patterning the photoresist using photolithography to form an opening that defines the location for the vertical trench in the substrate. Referring to the example of FIG. 10C, in an embodiment of block 932, a layer of photoresist 1008 is deposited over the substrate 1002 and the layer of photoresist 1008 is patterned to form an opening 1010 that defines the location for the subsequently formed vertical trench in the substrate 1002.

At block 934, the method 900 includes removing the exposed substrate under the opening to form the vertical trench. In various embodiments a dry etching technique may be used to remove the exposed substrate and form the vertical trench. Referring to the example of FIG. 10D, in an embodiment of block 934, the exposed substrate under the opening 1010 has been removed to form the vertical trench 1012.

At block 940, the method 900 includes forming a gate oxide layer over the substrate and in the vertical trench. Referring to the example of FIG. 10E, in an embodiment of block 940, a gate oxide layer 1014 is formed over the substrate 1002 and in the vertical trench 1012. In various embodiments, the gate oxide layer 1014 comprises a high κ dielectric. In various embodiments, the high κ dielectric is deposited on the substrate 1002 to line the vertical trench 1012 and isolate the subsequently formed vertical transfer gate from the substrate 1002. In various embodiments, the high κ dielectric includes one or more materials with a dielectric constant κ exceeding that of silicon dioxide (i.e., a dielectric constant κ exceeding 3.9). In various embodiments, the high κ dielectric may include HfO₂, AlO₃, and Ta₂O₅.

At block 950, the method 900 includes forming a gate poly region for a vertical transfer gate transistor over the gate oxide layer on the substrate and in the vertical trench. In various embodiments, the gate poly region has a plurality of wall sections that vertically extend into the substrate and laterally extend adjacent to a side of the pixel section (e.g., wall sections 306-1, 306-2, 306-3, and 306-4 of VTG structure 306; wall sections 406-1, 406-2, 406-3, and 406-4 of VTG structure 406; wall sections 506-1, 506-2, 506-3, and 506-4 of VTG structure 506; wall sections 606-1, 606-2, 606-3, and 606-4 of VTG structure 606). In various embodiments, forming a gate poly region for a vertical transfer gate transistor involves performing blocks 952, 954, 956, 958, and 959. In this example, each wall section extends a distance that is greater than half the length of the corresponding side to which the wall section is adjacent.

At block 952, the method 900 includes depositing a gate poly layer over the substrate including filling the vertical trench. In various embodiments, the gate poly layer includes a conductive material. In various embodiments, the gate poly layer comprises polysilicon, but other gate materials, such as metal, are amenable. Referring to the example of FIG. 10F, in an embodiment of block 952, a gate poly layer 1016 is deposited over the substrate 1002 and the vertical trench 1012 is filled with the gate poly layer 1016.

At block 954, the method 900 includes depositing a layer of photoresist over the gate poly layer on the substrate and, at block 956, the method 900 includes patterning the photoresist using photolithography to define the location of a gate poly region on the substrate for a vertical transfer gate. Referring again to the example of FIG. 10F, in an embodiment of blocks 954 and 956, photoresist 1018 has been deposited over the gate poly layer 1016 on the substrate and the photoresist 1018 has been patterned to define the location of a gate poly region on the substrate for a vertical transfer gate.

At block 958, the method 900 includes patterning the gate poly layer based on the patterned photoresist to form the gate poly region of the vertical transfer gate. Referring to the example of FIG. 10G, in an embodiment of block 958, the gate poly layer 1016 is patterned based on the photoresist 1018 to form the gate poly region 1020 of a vertical transfer gate.

At block 959, the method 900 includes removing the patterned photoresist layer. Referring to the example of FIG. 10H, in an embodiment of block 958, the patterned photoresist layer has been removed leaving the gate poly region 1020 of a vertical transfer gate in the substrate 1002.

At block 960, the method 900 includes performing further fabrication operations to complete an image sensor device.

In some aspects, the techniques described herein relate to a semiconductor structure, including: a plurality of pixel sections arranged in a substrate, each pixel section having a plurality of sides; and a first pixel section of the plurality of pixel sections including: a photo detector; and a vertical transfer gate (VTG) structure disposed above the photo detector, the VTG structure having a laterally extending body portion and a plurality of wall sections connected at different end regions of the body portion that vertically extend into the substrate wherein at least a first wall section of the plurality of wall sections laterally extends a first distance adjacent to a first side of the first pixel section and a second wall section of the plurality of wall sections laterally extends a second distance adjacent to a second side of the first pixel section, wherein the first distance is greater than half the length of the first side and the second distance is greater than half the length of the second side.

In some aspects, the techniques described herein relate to a semiconductor structure, wherein the first pixel section is separated from neighboring pixel sections of the plurality of pixel sections by an isolation layer at borders between the first pixel section and the neighboring pixel sections and wherein the plurality of wall sections are disposed in a portion of the pixel section isolated by the isolation layer.

In some aspects, the techniques described herein relate to a semiconductor structure, wherein the first pixel section is separated from neighboring pixel sections of the plurality of pixel sections without an isolation layer at borders between the first pixel section and the neighboring pixel sections.

In some aspects, the techniques described herein relate to a semiconductor structure, wherein the first pixel section is separated from a first neighboring pixel section without an isolation layer at a border between the first pixel section and the first neighboring pixel section, wherein the first pixel section is separated from a second neighboring pixel section by an isolation layer at a border between the first pixel section and the second neighboring pixel section, and wherein a wall section of the plurality of wall sections is disposed in a portion of the pixel section isolated from the second neighboring pixel section.

In some aspects, the techniques described herein relate to a semiconductor structure, wherein: the pixel section includes four sides and four corners; and the plurality of vertically extending wall sections includes four wall sections that extend laterally along the four sides of the pixel section.

In some aspects, the techniques described herein relate to a semiconductor structure, wherein adjacent to each of the four corners, two of the four wall sections connect.

In some aspects, the techniques described herein relate to a semiconductor structure, wherein adjacent to three of the four corners, two of the four wall sections connect, and adjacent to a fourth of the four corners, there is no connection between any of the four wall sections.

In some aspects, the techniques described herein relate to a semiconductor structure, including: a pixel region in a substrate; a photo detector in the pixel region; and a vertical transfer gate (VTG) structure disposed above the photo detector, the VTG structure having a laterally extending body portion and a plurality of wall sections connected to end regions of the body portion that vertically extend a predetermined depth into the substrate; wherein the predetermined depth is configured based on a wavelength band of captured light the photo detector is configured to detect.

In some aspects, the techniques described herein relate to a semiconductor structure, wherein the wavelength band is near infrared and the depth is approximately 6.0 to 20 micrometers (μm).

In some aspects, the techniques described herein relate to a semiconductor structure, wherein the wavelength band is clear and the depth is approximately 3.0 to 10 μm.

In some aspects, the techniques described herein relate to a semiconductor structure, wherein the wavelength band is red and the depth is approximately 3.0 to 6.0 μm.

In some aspects, the techniques described herein relate to a semiconductor structure, wherein the wavelength band is green and the depth is approximately 1.0 to 3.0 μm.

In some aspects, the techniques described herein relate to a semiconductor structure, wherein the wavelength band is blue and the depth is approximately 0.5 to 1.5 μm.

In some aspects, the techniques described herein relate to a semiconductor structure, wherein: the VTG structure includes more than two wall sections underneath the body portion that vertically extend a predetermined depth into the substrate; the more than two wall sections have different depths; and the different depths of two adjacent wall sections are configured for a particular wavelength band.

In some aspects, the techniques described herein relate to a semiconductor structure, wherein: the VTG structure includes four wall sections underneath the body portion and are configured for three different wavelength bands; and a first set of two adjacent wall sections has wall section depths that are configured for a first wavelength band, a second set of two adjacent wall sections has wall section depths that are configured for a second wavelength band, and a third set of two adjacent wall sections has wall section depths that are configured for a third wavelength band.

In some aspects, the techniques described herein relate to a method, including: providing a substrate; forming a vertical trench in a pixel sensor area of the substrate, wherein the trench laterally extends along a plurality of sides that bounds the pixel sensor area; forming a gate oxide layer in the vertical trench; and forming a gate poly region for a vertical transfer gate transistor over the gate oxide layer, wherein the gate poly region has a plurality of wall sections connected at different end regions of a body portion that vertically extend into the substrate wherein at least a first wall section of the plurality of wall sections laterally extends a first distance adjacent to a first side that bounds the pixel sensor area and a second wall section of the plurality of wall sections laterally extends a second distance adjacent to a second side that bounds the pixel sensor area, wherein the first distance is greater than half the length of the first side and the second distance is greater than half the length of the second side.

In some aspects, the techniques described herein relate to a method, wherein forming the gate poly region includes forming four wall sections that extend along four sides that bound the pixel sensor area.

In some aspects, the techniques described herein relate to a method, wherein: each of the four wall sections substantially extend an entire length along a side that bounds the pixel sensor area; and adjacent to each of four corners of the pixel sensor area, two of the four wall sections connect.

In some aspects, the techniques described herein relate to a method, wherein: each of the four wall sections substantially extend an entire length along a side that bounds the pixel sensor area; adjacent to three of four corners of the pixel sensor area, two of the four wall sections connect; and adjacent to a fourth of the four corners of the pixel sensor area, there is no connection between any of the four wall sections.

In some aspects, the techniques described herein relate to a method, wherein: the plurality of wall sections includes two wall sections that extend laterally along two of four sides of the pixel sensor area; and the two wall sections connect adjacent to a corner of the pixel sensor area.

While at least one exemplary embodiment has been presented in the foregoing detailed description of the disclosure, it should be appreciated that a vast number of variations exist. It should also be appreciated that the exemplary embodiment or exemplary embodiments are only examples, and are not intended to limit the scope, applicability, or configuration of the disclosure in any way. Rather, the foregoing detailed description will provide those skilled in the art with a convenient road map for implementing an exemplary embodiment of the disclosure. It being understood that various changes may be made in the function and arrangement of elements described in an exemplary embodiment without departing from the scope of the disclosure as set forth in the appended claims.

What is claimed is:

1. A semiconductor structure, comprising:
a plurality of pixel sections arranged in a substrate, each pixel section having a plurality of sides; and
a first pixel section of the plurality of pixel sections comprising:
a photo detector; and
a vertical transfer gate (VTG) structure disposed above the photo detector, the VTG structure having a laterally extending body portion and a plurality of wall sections connected at different end regions of the body portion that vertically extend into the substrate wherein at least a first wall section of the plurality of wall sections laterally extends a first distance adjacent to a first side of the first pixel section and a second wall section of the plurality of wall sections laterally extends a second distance adjacent to a second side of the first pixel section, wherein the first distance is greater than half the length of the first side and the second distance is greater than half the length of the second side.

2. The semiconductor structure of claim 1, wherein the first pixel section is separated from neighboring pixel sections of the plurality of pixel sections by an isolation layer at borders between the first pixel section and the neighboring pixel sections and wherein the plurality of wall sections are disposed in a portion of the pixel section isolated by the isolation layer.

3. The semiconductor structure of claim 1, wherein the first pixel section is separated from neighboring pixel sections of the plurality of pixel sections without an isolation layer at borders between the first pixel section and the neighboring pixel sections.

4. The semiconductor structure of claim 1, wherein the first pixel section is separated from a first neighboring pixel section without an isolation layer at a border between the first pixel section and the first neighboring pixel section, wherein the first pixel section is separated from a second neighboring pixel section by an isolation layer at a border between the first pixel section and the second neighboring pixel section, and wherein a wall section of the plurality of wall sections is disposed in a portion of the pixel section isolated from the second neighboring pixel section.

5. The semiconductor structure of claim 1, wherein:
the pixel section comprises four sides and four corners; and
the plurality of vertically extending wall sections comprises four wall sections that extend laterally along the four sides of the pixel section.

6. The semiconductor structure of claim 5, wherein adjacent to each of the four corners, two of the four wall sections connect.

7. The semiconductor structure of claim 5, wherein adjacent to three of the four corners, two of the four wall sections connect, and adjacent to a fourth of the four corners, there is no connection between any of the four wall sections.

8. A semiconductor structure, comprising:
a pixel region in a substrate;
a photo detector in the pixel region; and
a vertical transfer gate (VTG) structure disposed above the photo detector, the VTG structure having a laterally extending body portion and a plurality of wall sections connected to end regions of the body portion that vertically extend a predetermined depth into the substrate;
wherein the predetermined depth is configured based on a wavelength band of captured light the photo detector is configured to detect.

9. The semiconductor structure of claim 8, wherein the wavelength band is near infrared and the depth is approximately 6.0 to 20 micrometers (μm).

10. The semiconductor structure of claim 8, wherein the wavelength band is clear and the depth is approximately 3.0 to 10 μm.

11. The semiconductor structure of claim 8, wherein the wavelength band is red and the depth is approximately 3.0 to 6.0 μm.

12. The semiconductor structure of claim 8, wherein the wavelength band is green and the depth is approximately 1.0 to 3.0 μm.

13. The semiconductor structure of claim 8, wherein the wavelength band is blue and the depth is approximately 0.5 to 1.5 μm.

14. The semiconductor structure of claim 8, wherein:
the VTG structure comprises more than two wall sections underneath the body portion that vertically extend a predetermined depth into the substrate;
the more than two wall sections have different depths; and
the different depths of two adjacent wall sections are configured for a particular wavelength band.

15. The semiconductor structure of claim 14, wherein:
the VTG structure comprises four wall sections underneath the body portion and are configured for three different wavelength bands; and
a first set of two adjacent wall sections has wall section depths that are configured for a first wavelength band, a second set of two adjacent wall sections has wall section depths that are configured for a second wavelength band, and a third set of two adjacent wall sections has wall section depths that are configured for a third wavelength band.

16. A method, comprising:
providing a substrate;
forming a vertical trench in a pixel sensor area of the substrate, wherein the trench laterally extends along a plurality of sides that bounds the pixel sensor area;
forming a gate oxide layer in the vertical trench; and
forming a gate poly region for a vertical transfer gate transistor over the gate oxide layer, wherein the gate poly region has a plurality of wall sections connected at different end regions of a body portion that vertically extend into the substrate wherein at least a first wall section of the plurality of wall sections laterally extends a first distance adjacent to a first side that bounds the pixel sensor area and a second wall section of the plurality of wall sections laterally extends a second distance adjacent to a second side that bounds the pixel sensor area, wherein the first distance is greater than half the length of the first side and the second distance is greater than half the length of the second side.

17. The method of claim 16, wherein forming the gate poly region comprises forming four wall sections that extend along four sides that bound the pixel sensor area.

18. The method of claim 17, wherein:
each of the four wall sections substantially extend an entire length along a side that bounds the pixel sensor area; and
adjacent to each of four corners of the pixel sensor area, two of the four wall sections connect.

19. The method of claim 17, wherein:
each of the four wall sections substantially extend an entire length along a side that bounds the pixel sensor area;
adjacent to three of four corners of the pixel sensor area, two of the four wall sections connect; and
adjacent to a fourth of the four corners of the pixel sensor area, there is no connection between any of the four wall sections.

20. The method of claim 16, wherein:
the plurality of wall sections comprises two wall sections that extend laterally along two of four sides of the pixel sensor area; and
the two wall sections connect adjacent to a corner of the pixel sensor area.
